(19) United States
(12) Patent Application Publication
(10) Pub. No.: US 2026/0250805 A1
(43) Pub. Date: Aug. 27, 2026

(54) HEAT DISSIPATION MATERIAL, HEAT DISSIPATION COMPONENT, ELECTROSTATIC CHUCK, AND METHOD FOR PRODUCING HEAT DISSIPATION MATERIAL

(71) Applicant: KABUSHIKI KAISHA KOBE SEIKO SHO (KOBE STEEL, LTD.), Kobe-shi (JP)

(72) Inventors: Takeo MIYAMURA, Hyogo (JP); Masahiro INOMOTO, Hyogo (JP)

(73) Assignee: KABUSHIKI KAISHA KOBE SEIKO SHO (KOBE STEEL, LTD.), Kobe-shi (JP)

(21) Appl. No.: 19/489,733

(22) PCT Filed: May 14, 2024
(86) PCT No.: PCT/JP2024/017756

§ 371 Date: Dec. 3, 2025

(30) Foreign Application Priority Data
Jun. 5, 2023 (JP) 2023-092511
Apr. 2, 2024 (JP) 2024-059528

(51) Int. Cl. C22C 27/00; C22C 1/04; H10P 72/72

(52) U.S. Cl. CPC C22C 27/00; C22C 1/045; H10P 72/722

(57) ABSTRACT

A heat dissipation material for a heat dissipation component can be suitably used in a treatment with a large heat input, and may be included in a heat dissipation component. An electrostatic chuck may include the heat dissipation component. The heat dissipation material may contain a Mo phase and a Ti phase in coexistence, in which the heat dissipation material contains 3 atomic % or more and 50 atomic % or less of Ti, a remainder being Mo. A method for producing a heat dissipation material may includes mixing a powder containing Mo and a powder containing Ti to obtain a mixture, and sintering the mixture.

### TECHNICAL FIELD

The present invention relates to a heat dissipation material that can be suitably used particularly in a treatment step with a large heat input, a heat dissipation component containing the heat dissipation material, an electrostatic chuck, and a method for producing the heat dissipation material.

### BACKGROUND ART

In general, during production of a semiconductor device, a thin film forming step and an etching step on a silicon wafer are repeatedly performed to form fine interconnection and semiconductor elements. As a method of fixing a wafer during the etching step, an electrostatic chuck is used. Specifically, the wafer is placed on a ceramic layer formed of a ceramic (for example, Al₂O₃ and Y₂O₃), and the wafer is fixed by a force of static electricity. During the etching step, the wafer is heated by the influence of plasma or the like. Therefore, a base plate serving as a heat dissipation material is bonded under the ceramic layer to cool the wafer during the etching step.

Patent Literature 1 discloses an electrostatic chuck using aluminum or an aluminum alloy as a material of a base plate.

### CITATION LIST

### Patent Literature

Patent Literature 1: JP2017-103389A

### SUMMARY OF INVENTION

### Technical Problem

However, in recent years, high integration of semiconductors has progressed, and the heat input during etching is increasing.

The present invention has been made in view of such a problem, and an object of the present invention is to provide a heat dissipation material that can be suitably used in a treatment step with a large heat input, a heat dissipation component, an electrostatic chuck including the heat dissipation component, and a method for producing the heat dissipation material.

### Solution to Problem

The above object of the present invention is achieved by the following configuration [1] relating to a heat dissipation material.

[1] A heat dissipation material containing:
a Mo phase; and
a Ti phase coexistent with the Mo phase, in which
the heat dissipation material contains 3 atomic % or more and 50 atomic % or less of Ti and Mo as a remainder.

In addition, a preferred embodiment of the present invention relating to the heat dissipation material relates to the following [2].

[2] The heat dissipation material according to [1], the material consisting of:
Ti: 3 atomic % or more and 50 atomic % or less in a case where a total of a content of Ti and a content of Mo is 100 atomic %,
O: 0 atomic % or more and 3 atomic % or less in the case where the total of the content of Mo and the content of Ti is 100 atomic %,
N, C, Fe, Si, Mn, Mg, Cl, Al, V, Mn, Ni, and Nb: each 0 atomic % or more and 1 atomic % or less in the case where the total of the content of Mo and the content of Ti is 100 atomic %, and
the remainder being Mo and unavoidable impurities.

The above object of the present invention is achieved by the following configuration [3] relating to a heat dissipation material.

[3] A heat dissipation material containing:
a Mo phase; and
a Ti phase coexistent with the Mo phase, in which
the heat dissipation material contains 3 atomic % or more and 50 atomic % or less of Ti, a remainder being Mo.

In addition, preferred embodiments of the present invention relating to the heat dissipation material relate to the following [4] and [5].

[4] The heat dissipation material according to any one of [1] to [3], in which in a case where a ratio of the Mo phase in the heat dissipation material is defined as [Mo phase] in atomic % and a concentration of all the Mo contained in the heat dissipation material is defined as [total Mo] in atomic %, an alloying ratio A represented by the following equation (1) is 15% or more and 80% or less, as measured by using an X-ray diffraction method.

$$A = ( 1 - [ Mo phase ] / [ total Mo ] ) \times 100 \qquad Equation ( 1 )$$

[5] The heat dissipation material according to any one of [1] to [4], in which the heat dissipation material is for use in an electrostatic chuck including a base plate, a ceramic layer provided on the base plate, and an electrode configured to generate static electricity on a surface of the ceramic layer, and is used as a material of the base plate.

The above object of the present invention is achieved by the following configuration [6] relating to a heat dissipation component.

[6] A heat dissipation component containing: the heat dissipation material according to any one of [1] to [5].

The above object of the present invention is achieved by the following configuration [7] relating to an electrostatic chuck.

[7] An electrostatic chuck including: a base plate including the heat dissipation component according to [6]; a ceramic layer provided on the base plate; and an electrode configured to generate static electricity on a surface of the ceramic layer.

The above object of the present invention is achieved by the following configuration [8] relating to a method for producing a heat dissipation material.

[8] A method for producing a heat dissipation material, which is a method for producing the heat dissipation material according to according to any one of [1] to [5], the method including:
a mixing step of mixing a powder containing Mo and a powder containing Ti to obtain a mixture; and
a sintering step of sintering the mixture.

### Advantageous Effects of Invention

According to the present invention, it is possible to provide a heat dissipation material that can be suitably used in a treatment step with a large heat input, a heat dissipation component, an electrostatic chuck including the heat dissipation component, and a method for producing the heat dissipation material.

### BRIEF DESCRIPTION OF DRAWINGS

FIG. 1 is a drawing substitute photograph obtained by capturing a structure of a heat dissipation material according to the present embodiment using a scanning electron microscope.

FIG. 2 is a schematic cross-sectional view showing an example of an electrostatic chuck according to an embodiment of the present invention.

FIG. 3 is a graph showing measurement results for Inventive Examples and Comparative Examples in the case where a vertical axis represents a thermal conductivity and a horizontal axis represents a linear expansion coefficient.

FIG. 4 is a graph showing a relationship between a relative density and an alloying ratio in the case where the vertical axis represents the relative density and the horizontal axis represents the alloying ratio.

### DESCRIPTION OF EMBODIMENTS

The present inventors have conducted intensive studies on a material for a heat dissipation component that can be applied particularly in a treatment step with a large heat input.

As described above, the heat input during the etching has increased due to the high integration of semiconductors in recent years. However, an aluminum alloy used as a material for a base plate in the related art is poor in softening resistance, and a heat treatment (aging treatment) in a production stage of the aluminum alloy is performed at a temperature up to about 200° C. Therefore, when the temperature of the base plate is higher than 200° C. in an etching step, material properties of the aluminum alloy cannot be maintained.

In addition, when a heat dissipation component is applied to a treatment step with a large heat input, the influence of thermal expansion of the heat dissipation component increases, and the heat dissipation component and a surrounding material may have greatly different size change rates. As a result, a strain is generated between the heat dissipation component and the surrounding material, and this strain causes peeling off or cracking of the surrounding material.

Further, in order to apply the heat dissipation component to a treatment step with a large heat input, it is necessary to exhibit a high heat dissipation property.

That is, in order to apply the heat dissipation component to a treatment step with a large heat input, it is important that the heat dissipation component has high softening resistance, an appropriate thermal expansion coefficient, and a high thermal conductivity. Then, the present inventors have found that a heat dissipation component having desired properties can be obtained by using, as a heat dissipation component, a material in which a Mo phase and a Ti phase coexist and a content of Ti is appropriately controlled. Further, the present inventors have found that a good relative density can be obtained and a highly reliable heat dissipation material can be produced by controlling alloying ratios of Mo and Ti within an appropriate range. The present invention has been made based on these findings.

Hereinafter, an embodiment of a heat dissipation material for realizing high softening resistance, an appropriate linear expansion coefficient, and a high thermal conductivity will be described in detail.

### [Heat Dissipation Material]

Among aluminum alloys, 2000 series aluminum alloys, which are said to have high softening resistance, have a tensile proof stress decreased to 200 MPa at a temperature of 200° C. (Katsumi Koyama, “High Strength and Softening Resistant Aluminum Alloy”, Furukawa-Sky Review, No. 6, 2010, p. 13, FIG. 7).

On the other hand, Mo is a high melting point metal having a melting point of 2,623° C. and has extremely excellent softening resistance at a temperature of about 200° C. Specifically, Mo has a tensile strength value of 550 MPa or more at 200° C. (Takashi Murakami et al., “Molybdenum and Molybdenum Alloy”, JOURNAL OF THE JAPAN WELDING SOCIETY, Vol. 57, (1988), No. 4, p. 293, FIG. 2).

Since a heat dissipation material according to the present embodiment contains Mo as a main component, the softening resistance can be greatly improved. In addition, Mo is one of pure metals having a high thermal conductivity, and has a thermal conductivity of 2 times or more of iron and 8 times or more of titanium. Therefore, when the heat dissipation material contains Mo as a main component, a high heat dissipation property can be exhibited.

In addition, the present inventors have found that in order to obtain a heat dissipation material having a particularly desired linear expansion coefficient, it is effective to make a Mo phase and a Ti phase coexist instead of completely dissolving Ti in Mo, and more specifically, Ti has a linear expansion coefficient larger than that of Mo and the obtained alloy has a linear expansion coefficient that can be brought close to that of a material of a ceramic layer. However, when the Ti phase is not dispersed, the effect of adding Ti is weakened, and the linear expansion coefficient of the heat dissipation material approaches the linear expansion coefficient of Mo.

As to be described in detail later, the heat dissipation material according to the present embodiment is a sintered body obtained by mixing and sintering a Mo powder and a Ti powder, and more specifically, is a sintered composite having a structural form in which a Mo phase (body-centered cubic structure) and a Ti phase (hexagonal close-packed structure or body-centered cubic structure) coexist. Since this sintered composite has properties such as inclusion of pores, it can be checked that it is a sintered body by observing the structure.

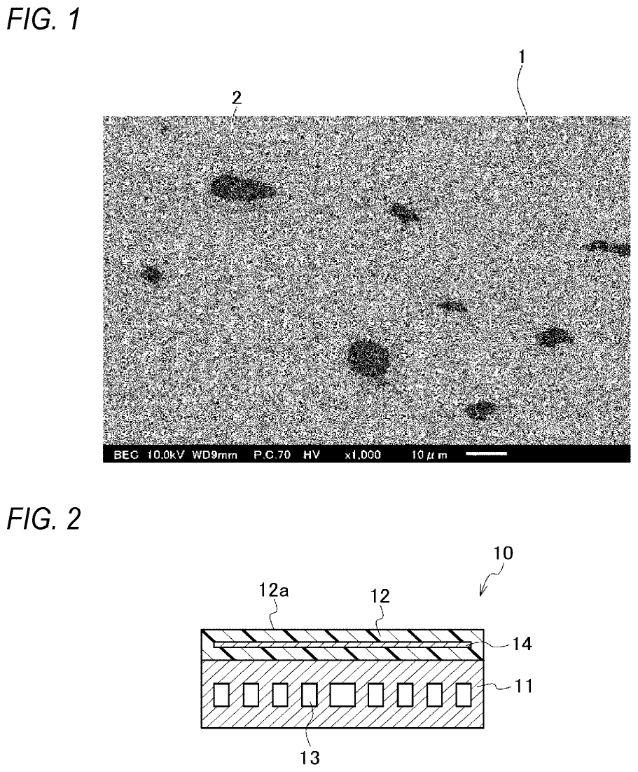

FIG. 1 is a drawing substitute photograph obtained by capturing a structure of a heat dissipation material according to Inventive Example No. 3 to be described later using a scanning electron microscope. As shown in FIG. 1, in the heat dissipation material according to the present embodiment, a black Ti phase 2 is dispersed in a Mo phase 1 as a main component. In this manner, in the present embodiment, it is shown that a metal/metal-based composite material is formed. In addition, since the Ti phase 2 has an effect of increasing the linear expansion coefficient, by adjusting a content of Ti, it is possible to obtain a heat dissipation material for a heat dissipation component that is suitably used in a treatment step with a large heat input.

A content of the component contained in the heat dissipation material in the present embodiment will be described below.

### (Ti: 3 Atomic % or More and 50 Atomic % or Less)

When a content of Ti in the heat dissipation material is less than 3 atomic %, the effect of increasing the linear expansion coefficient of the heat dissipation material cannot be sufficiently obtained, and there is a concern that peeling off of a ceramic layer (an Al₂O₃ layer, a Y₂O₃ layer, or the like) from a base plate or cracking of the ceramic layer may occur. Therefore, the content of Ti in the heat dissipation material is 3 atomic % or more, preferably 4 atomic % or more, and more preferably 8 atomic % or more.

On the other hand, when the content of Ti in the heat dissipation material is more than 50 atomic %, the thermal conductivity decreases, and the properties required as the heat dissipation material cannot be obtained. Therefore, the content of Ti in the heat dissipation material is 50 atomic % or less, preferably 45 atomic % or less, and more preferably 35 atomic % or less.

In this manner, by appropriately adjusting the content of Ti in the heat dissipation material, the linear expansion coefficient can be adjusted to the same degree as that of the ceramic layer (an Al₂O₃ layer, a Y₂O₃ layer, or the like), the peeling off of the ceramic layer (an Al₂O₃ layer, a Y₂O₃ layer, or the like) from the base plate can be prevented, and an excellent heat dissipation property can be obtained.

Note that, in the case where the ratio of Ti or Mo in the heat dissipation material in the present specification is expressed in atomic %, the ratio of Ti atoms or Mo atoms is expressed in atomic % when a total of Ti atoms and Mo atoms in the heat dissipation material is 100 atomic %.

### (Remainder: Mo)

The heat dissipation material according to the present embodiment contains Ti in the above range, and the remainder is Mo. Therefore, excellent softening resistance can be obtained, and properties having both a large thermal conductivity and an appropriate linear expansion coefficient can be obtained.

Note that, the heat dissipation material according to the present embodiment is free of Cu. When Cu is present in a chamber in the etching step, the inside of the chamber is contaminated with Cu, which influence an interconnection structure. Therefore, the heat dissipation material free of Cu according to the present embodiment can be particularly suitably used in the etching step.

The heat dissipation material according to the present embodiment may contain various impurities as long as the effects of the present invention are not impaired. Examples of the impurities include oxygen (O), nitrogen (N), and carbon (C) derived from powder raw materials. In addition, Fe, Si, Mn, Mg, Cl, Al, V, Mn, Ni, Nb, or the like may be contained. In these impurities, it is empirically considered preferable to prevent oxygen (O) to 3 mass % or less, and the other elements to, for example, 1 mass % or less or 0.3 mass % or less for each, and to, for example, 5 mass % or less or 3 mass % or less in total.

Note that, the content of the impurities is represented by mass % of the impurity content in the case where a total of a content of Mo and the content of Ti in the heat dissipation material according to the present embodiment is 100 mass %.

In addition, as long as these elements are within the above numerical ranges, the effect of the present embodiment is not impaired not only in the case where these elements are contained as unavoidable impurities but also in the case where these elements are positively added.

The present inventors have found that, in addition to an excellent thermal conductivity and linear expansion coefficient, a good relative density can be obtained by controlling alloying ratios of Mo and Ti within an appropriate range. Hereinafter, the alloying ratios of Mo and Ti will be described in more detail.

### <Alloying Ratio A: 15% or More and 80% or Less>

In a mixed powder obtained by mixing a pure Mo powder and a pure Ti powder, atomic diffusion occurs in a sintering stage, and an alloyed region is formed between Mo and Ti. The present inventors have found that this alloyed region has a smaller hot deformation resistance than pure Mo alone, and as the alloying ratio increases, sintering is promoted and the relative density is increased. That is, in the case where a heat dissipation component containing a heat dissipation material having a low relative density is used for a base plate, there is a concern that a refrigerant for cooling the base plate may leak, or cracking or breakage may be promoted due to a thermal stress or a mechanical stress caused by repeated use of the base plate.

Therefore, obtaining a heat dissipation material having a good relative density leads to production of a highly reliable base plate. In the present description, the alloying ratio is defined as a ratio of Mo consumed by alloying to all Mo contained in the heat dissipation material.

A method for measuring the alloying ratio will be described below. First, the heat dissipation material after sintering is measured by using an X-ray diffraction method (XRD). Next, a spectrum obtained by the XRD is analyzed by using a whole powder pattern fitting method (WPPF), and an atomic fractions (atomic %) of the Mo phase, a MoₓTi_{y} phase, and the Ti phase are determined. Then, using these values, the alloying ratio can be measured according to the following equation (1).

In the present embodiment, when the alloying ratio A represented by the following equation (1) is defined, a heat dissipation material having a good relative density can be obtained. In the following equation (1), the [Mo phase] is a value representing a ratio of the Mo phase in the heat dissipation material in atomic %, and the [total Mo] is a value representing a concentration of all Mo contained in the heat dissipation material in atomic %, as determined by using the X-ray diffraction method.

Note that, the concentration of Mo in the heat dissipation material is a ratio of Mo atoms expressed in atomic % in the case where the total of the Ti atoms and the Mo atoms in the heat dissipation material is 100 atomic %. In addition, the ratio of the Mo phase in the heat dissipation material is the ratio of the Mo atoms constituting the Mo phase expressed in atomic % in the case where all atoms constituting the Mo phase, the MoₓTi_{y} phase, and the Ti phase in the heat dissipation material are 100 atomic %.

More specifically, the [Mo phase] can be determined based on a mass fraction of the Mo phase, among mass fractions (100 mass % in total) of the Mo phase, the MoₓTi_{y} phase, and the Ti phase determined by the whole powder pattern fitting method, according to the following equation (2). In the following equation (1), the alloying ratio A calculated using atomic % is a value same as the alloying ratio calculated using mass % instead of atomic %.

Although details will be described later, the heat dissipation material can be produced by mixing a powder containing Mo and a powder containing Ti to prepare a mixture and sintering the mixture. Therefore, in general, the concentrations during the mixing of the Ti powder and the Mo powder are often the concentration of Ti and the concentration of Mo in the heat dissipation material after the sintering. Therefore, if it can be found that there is only a difference within a degree of error between the concentration during the mixing and the concentration in the heat dissipation material after the sintering, the concentration of Mo during the powder mixing can be used as the concentration of Mo ([total Mo]) in the heat dissipation material.

$$A = ( 1 - [ Mo phase ] / [ total Mo ] ) \times 100 \qquad Equation ( 2 )$$

$$[ Mo phase ] = ( \{ Mo phase \} / atomic weight of Mo ) / ( [ content of Mo ] / atomic weight of Mo + [ content of Ti ] / atomic weight of Ti )$$

In the above equation (2), the [Mo phase] is a value representing the ratio of the Mo phase in the heat dissipation material in atomic %, as determined by using the X-ray diffraction method.

The {Mo phase} is the mass fraction of the Mo phase determined by using the XRD, and is a value representing the ratio of the Mo phase in mass % in the case where the total of the Mo phase, the MoₓTi_{y} phase, and the Ti phase is 100 mass %.

The [content of Mo] is a value representing the content of all Mo contained in the heat dissipation material in mass %.

The [content of Ti] is a value representing the content of all Ti contained in the heat dissipation material in mass %.

When the alloying ratio A calculated according to the above equation (1) is 15% or more, a higher relative density can be obtained, and the occurrence of cracking or breakage due to the load of a thermal stress or a mechanical stress can be prevented. Therefore, the alloying ratio A calculated according to the above equation (1) is preferably 15% or more, more preferably 30% or more, and still more preferably 40% or more.

In addition, when the alloying ratio A calculated according to the above equation (1) is 80% or less, it is possible to prevent a temperature required for the sintering from being too high and a time required for the sintering from being too long, and it is possible to prevent wear of a sintering mold and maintain good productivity. Therefore, the alloying ratio A calculated according to the above equation (1) is preferably 80% or less, more preferably 70% or less, and still more preferably 60% or less. By controlling the alloying ratio A to such an alloying ratio, a heat dissipation material having a high relative density in addition to a good thermal conductivity and linear expansion coefficient can be obtained. In the case where a heat dissipation component containing such a heat dissipation material is used for a base plate, performance and reliability as the base plate can be improved.

Here, an example of conditions for producing the heat dissipation material having the alloying ratio in the above range will be described. The alloying ratio is due to atomic diffusion of Mo and Ti, and in order to control the alloying ratio, the alloying ratio can be controlled by changing the temperature or the time required for a treatment in a subsequent step in which a thermal load is applied, such as a sintering step or bonding performed as necessary. For example, the sintering and the bonding can be performed under conditions according to the properties of a facility and the powder, with a thermal load of 800° C. to 1,400° C., a holding time of 5 minutes to 16 hours, and a pressure of 2 MPa to 50 MPa as guides.

Further, the relative density will be described below. In the present embodiment, by controlling the alloying ratio A within an appropriate range, a good relative density can be obtained, and as a result, a highly reliable heat dissipation material can be obtained. A relative density D can be determined by dividing a value of a density dₘ obtained by using an underwater substitution method (Archimedes method) or the like by a theoretical density dₜ, and expressing the result as 100 fraction. That is, the relative density D can be expressed according to the following equation (3).

$$D = ( {d}_{m} / {d}_{t} ) \times 100 \qquad Equation ( 3 )$$

Note that, the theoretical density dₜ can be calculated according to the following equation (4).

$${d}_{t} = 100 / ( [ content of Ti ] / [ specific gravity of Ti ] + [ content of Mo ] / [ specific gravity of Mo ] ) \qquad Equation ( 4 )$$

In the above equation (4), the [content of Ti] is a value representing the content of Ti contained in the heat dissipation material in mass %, and the [specific gravity of Ti] is a value representing the specific gravity of pure Ti. In addition, the [content of Mo] is a value representing the content of Mo contained in the heat dissipation material in mass %, and the [specific gravity of Mo] is a value representing the specific gravity of pure Mo.

The relative density D is preferably 98% or more, more preferably 98.5% or more, still more preferably 99% or more, and still more preferably 99.5% or more. Further, the relative density D is preferably 100.0% or more, more preferably 100.5% or more, and still more preferably 101.0% or more.

### [Heat Dissipation Component]

A heat dissipation component according to the present embodiment is obtained by machining the heat dissipation material (sintered composite) according to the present embodiment, and has properties of having excellent softening resistance, a high thermal conductivity, and an appropriate linear expansion coefficient. Therefore, when this heat dissipation component is used, heat can be sufficiently dissipated in a treatment step with a large heat input. In addition, since the heat dissipation component has an appropriate linear expansion coefficient, even in the case where the influence of thermal expansion increases in a step with a large heat input, the size change rate of the surrounding material and the size change rate of the heat dissipation component have close values. Therefore, it is possible to prevent the generation of the strain between the heat dissipation component and the surrounding material, and it is possible to prevent the occurrence of peeling off or cracking in the surrounding material.

### [Electrostatic Chuck]

FIG. 2 is a schematic cross-sectional view showing an example of an electrostatic chuck according to an embodiment of the present invention. As shown in FIG. 2, an electrostatic chuck 10 includes a base plate 11 formed of the above heat dissipation component, a ceramic layer 12 provided on the base plate 11, and an electrode 14 that generates static electricity on a surface 12a of the ceramic layer 12. A refrigerant flow path 13 is provided inside the base plate 11. Note that, the electrostatic chuck holds a member by using a force of static electricity, and the electrostatic chuck can be applied to a semiconductor production apparatus, an electrostatic robot hand, or the like.

Examples of the semiconductor production apparatus include various types of apparatuses such as a polishing apparatus, a developing apparatus, an exposure apparatus, and an etching apparatus. For example, the etching apparatus includes the electrostatic chuck 10 according to the present embodiment and a plasma generation/processing chamber in which the electrostatic chuck 10 is disposed. In the case where the electrostatic chuck 10 according to the present embodiment is used in an etching apparatus, a silicon wafer (not shown) is placed on the electrostatic chuck 10 disposed in a plasma generation/processing chamber, and a voltage is applied to the electrode 14 to generate static electricity on the surface of the ceramic layer 12, thereby fixing the silicon wafer. Then, under a vacuum atmosphere, the wafer surface is etched by using plasma in the plasma generation/processing chamber. Since the plasma has a high temperature and the temperature rises when the etching treatment is performed, the wafer is cooled by flowing a refrigerant through the refrigerant flow path 13 formed in the base plate 11.

As described above, since the heat input during the etching is increased due to the high integration of semiconductors in recent years, high softening resistance is required for the base plate. The heat dissipation material and the heat dissipation member according to the present embodiment are suitably used in a treatment step with a large heat input. That is, when the electrostatic chuck according to the present embodiment is used, the silicon wafer can be effectively cooled even in a high-temperature etching step corresponding to refinement and high integration of semiconductor devices. In addition, since the heat dissipation component has an appropriate linear expansion coefficient, it is possible to prevent the generation of the strain between the ceramic layer and the base plate even in the etching step as described above, and it is possible to prevent the occurrence of peeling off or cracking in the ceramic layer. Further, since Cu is not contained in the heat dissipation component constituting the base plate, the inside of the etching chamber can be prevented from being contaminated even when the heat dissipation component is used in the etching step. Therefore, the electrostatic chuck according to the present embodiment is preferably used particularly in an etching apparatus.

### [Method for Producing Heat Dissipation Material]

A method for producing a heat dissipation material according to the present embodiment is a method for producing the above heat dissipation material, and includes a mixing step of mixing a powder containing Mo and a powder containing Ti to obtain a mixture, and a sintering step of sintering the mixture.

A sintering method in the sintering step is not particularly limited, and for example, a spark plasma sintering (SPS) method, a hot press method, a hot isostatic pressing (HIP) method, or the like can be used. In addition, sintering conditions in the sintering step are not particularly limited, and for example, the sintering can be performed under conditions according to the properties of the facility and the properties of the powder with a sintering temperature of about 800° C. to 1,600° C., a sintering holding time of 5 minutes to 3 hours, and a pressure of 10 MPa to 50 MPa as guides.

Note that, in the present specification, the powder containing Mo and the powder containing Ti used as the material of the heat dissipation material include a case where oxygen, nitrogen, carbon, or the like derived from the powder raw materials is contained as an impurity. For example, an alloy powder may be used as the material of the heat dissipation material as long as the effect of the present invention is not impaired.

In addition, a heat dissipation component such as a base plate can be produced by performing contour processing and groove processing on a material obtained by sintering using the SPS method or the hot press method or a material obtained by sintering using the HIP method and then forging. Further, by forming a ceramic layer on an upper surface of the obtained heat dissipation component by diffusion bonding and then performing finishing by cutting, an electrostatic chuck in which the base plate and the ceramic layer are bonded to each other can be produced. Note that, examples of a method of bonding the base plate to the ceramic include brazing, bonding using an adhesive, and fixing using a screw, in addition to the diffusion bonding.

The heat dissipation material, the heat dissipation component, the electrostatic chuck, and the method for producing a heat dissipation material according to the present invention are not limited to the above embodiments, and can be freely modified and implemented without departing from the gist of the present invention.

In the above embodiments, the embodiment in which the heat dissipation component is used as the base plate of the electrostatic chuck used during the etching of the semiconductor production apparatus has been described. However, the present invention is not limited thereto, and the heat dissipation material and the heat dissipation component according to the present invention can be used as any heat dissipation material and any heat dissipation component. Since the heat dissipation material according to the present invention has the properties described above, it is suitably used as a material for a heat dissipation component for use in a treatment step with a large heat input particularly.

### EXAMPLES

Hereinafter, the heat dissipation material according to the present invention will be described more specifically with reference to Inventive Examples and Comparative Examples. However, the present invention is not limited to these Examples, and can be carried out by adding changes within the scope of the present invention, all of which are included in the technical scope of the present invention. In addition, the heat dissipation material and the production conditions thereof described below are merely examples, and the present invention is not limited to the following examples.

### Example 1

### (Production of Heat Dissipation Material)

First, a Mo powder and a Ti powder were mixed to obtain a mixture such that Mo—Ti sintered composites were formed with various compositions. Thereafter, the obtained mixture was sintered by a powder sintering method using a hot press method or an SPS method to produce sintered bodies in Inventive Example No. 1 to Inventive Example No. 4. In addition, only the Mo powder was sintered to produce a sintered body as Comparative Example No. 1. In Comparative Example No. 2, Comparative Example No. 3, and Comparative Example No. 4, known alumina (Al₂O₃), pure aluminum, and a 2000 series aluminum alloy, i.e., a 2024-T6 alloy known as duralumin were used.

Note that, in Inventive Example No. 1, Inventive Example No. 2, and Comparative Example No. 1, the sintering was performed by using a hot press method, and in Inventive Example No. 3 and Inventive Example No. 4, the sintering was performed by using an SPS method.

### (Component Analysis)

The components in Inventive Example No. 1 to Inventive Example No. 4 were analyzed by inductively coupled plasma (ICP) emission spectroscopy. The analysis results of the components in the heat dissipation materials in Inventive Examples and the materials of the sintered bodies in Comparative Examples are shown in Tables 1 and 2 below. Note that, in the compositions shown in Table 1, the ratio of the Ti atoms and the ratio of the Mo atoms are expressed in atomic % in the case where a total of the Ti atoms and the Mo atoms is 100 atomic %.

### (Measurement of Thermal Conductivity)

For the obtained sintered body, a specific heat at room temperature was measured by using a differential scanning calorimetry (DSC), a thermal diffusivity was measured by using a flash method, and the thermal conductivity was calculated based on these values.

### (Measurement of Linear Expansion Coefficient)

The linear expansion coefficient of the obtained sintered body was measured at 40° C. to 400° C. by using thermomechanical analysis (TMA method).

### (Observation of Material Structure)

The obtained sintered body was mirror-polished, and the material structure was observed by capturing a backscattered electron image using a scanning electron microscope.

The measurement results of the thermal conductivity and the linear expansion coefficient are shown in Tables 1 and 2 below. Note that, for the thermal conductivity and the linear expansion coefficient of Al₂O₃ in Comparative Example No. 2, the values of the material symbol “AO476O” described in the homepage of KYOCERA Japan (“Alumina Al₂O₃”, [searched on Dec. 13, 2022], Internet <URL;https://www.kyocera.co.jp/prdct/fc/material-property/material/alumina/index.html>) were cited. In addition, for the thermal conductivity and the linear expansion coefficient of pure Al in Comparative Example No. 3, the values described in “Metallic Data Book” (edited by The Japan Institute of Metals and Materials, Maruzen, 2004) were cited. Further, for the thermal conductivity and the linear expansion coefficient of the Al alloy (2024-T6) in Comparative Example No. 4, the values described in “Aluminum Handbook”, Japan Aluminum Association, 2007) were cited.

In Table 2 shown below, the thermal conductivity of pure Al is a measured value at 200° C., and the linear expansion coefficient is a measured value at 20° C. to 400° C. The linear expansion coefficient of the Al alloy shown in Table 2 below is a measured value at 20° C. to 300° C.

TABLE 1

| | | Composition | | Thermal | Linear expansion |
|---|---|---|---|---|---|
| | | (atomic %) | | conductivity | coefficient |
| No. | | Mo | Ti | (W/m · K) | (ppm/° C.) |
| Inventive | 1 | 90.1 | 9.9 | 83.1 | 5.97 |
| Example | 2 | 79.9 | 20.1 | 54.8 | 6.31 |
| | 3 | 95.0 | 5.0 | 87.7 | 5.68 |
| | 4 | 67.3 | 32.7 | 33.5 | 6.76 |

TABLE 2

| | | | Thermal | Linear expansion |
|---|---|---|---|---|
| | | | conductivity | coefficient |
| No. | | Material | (W/m · K) | (ppm/° C.) |
| Comparative | 1 | Mo- 0 atomic % | 121.4 | 5.43 |
| Example | | of Ti | | |
| | 2 | Al₂O₃ | 24 | 7.20 |
| | 3 | Pure Al | 238 | 26.5 |
| | 4 | Al alloy (2024-T6) | 150 | 24.7 |

### Evaluation of Inventive Examples and Comparative Examples

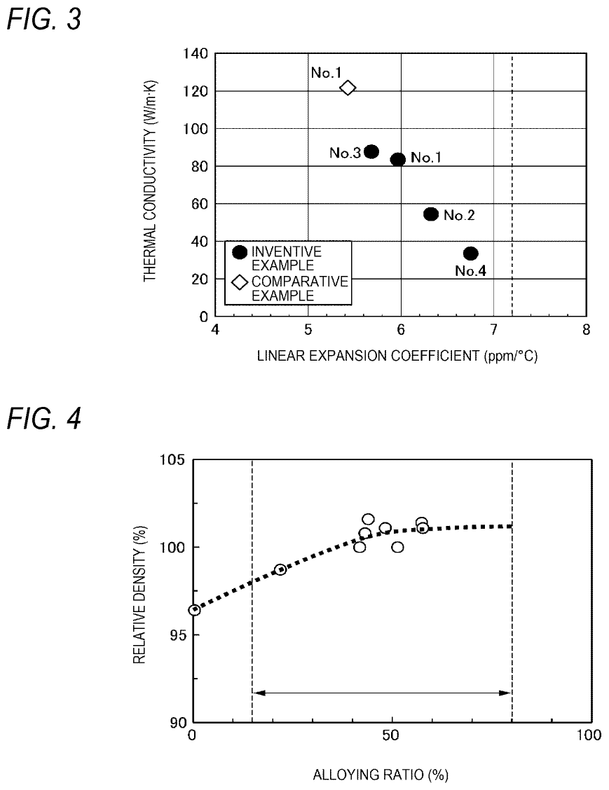

FIG. 3 is a graph showing the measurement results for Inventive Examples and Comparative Examples in the case where a vertical axis represents the thermal conductivity and a horizontal axis represents the linear expansion coefficient. Note that, the dotted line in the figure indicates the linear expansion coefficient of alumina. FIG. 1 is a micrograph obtained by capturing a structure of Inventive Example No. 3. As a result of observing the material structures of Inventive Example Nos. 1 to 4, it is found that the Mo phase and the Ti phase coexist in all Inventive Examples as in the micrograph shown in FIG. 1. In addition, as shown in Tables 1 and 2 above, the linear expansion coefficients of the sintered bodies in Inventive Example Nos. 1 to 4 are larger than the linear expansion coefficient of the sintered body in Comparative Example No. 1 free of Ti, and are close to the linear expansion coefficient of Al₂O₃ used as the material of the electrostatic chuck. In particular, the linear expansion coefficients of the sintered bodies in Inventive Example Nos. 1 to 4 are extremely close to the linear expansion coefficient of alumina in Comparative Example No. 2 as compared with the related-art materials in Comparative Example Nos. 3 and 4. Further, it is found that when the sintered bodies in, Inventive Example Nos. 1 to 4 are compared, the linear expansion coefficient increases as the concentration of Ti in the sintered body increases, and is close to the linear expansion coefficient of Al₂O₃.

From the above results, it is shown that in the case where a heat dissipation component is produced using the sintered bodies in Inventive Example Nos. 1 to 4, the obtained heat dissipation component has an excellent heat dissipation property. In addition, since the linear expansion coefficient is close to that of the ceramic layer formed of alumina to be bonded to the heat dissipation component, the occurrence of cracking, peeling off, or the like of the ceramic layer can be prevented. Further, the sintered bodies in Inventive Example Nos. 1 to 4 contain Mo as a main component and a predetermined amount of Ti, and have high softening resistance since all of these components have high softening resistance. Furthermore, since the sintered bodies in Invention Inventive Example Nos. 1 to 4 are free of Cu, contamination in the chamber can be prevented in the case where a heat dissipation component formed of these sintered bodies is used in the etching step for the semiconductor production apparatus.

### Example 2

### (Production of Heat Dissipation Material)

A pure Mo powder and a pure Ti powder were mixed and the mixture was sintered by a powder process using hot pressing and SPS to produce a Mo—Ti sintered body (heat dissipation material).

(Measurement of Concentration of Ti Powder During Mixing and Concentration of Ti in Heat Dissipation Material after Sintering)

Separately from the production of the heat dissipation material, the Mo powder and the Ti powder were mixed at various ratios, and the concentration of the Ti powder during the mixing of the Mo powder and the Ti powder was calculated. In addition, the mixture obtained by mixing was sintered by a powder process using hot pressing and SPS to produce a test piece of a sintered body. Thereafter, for each test piece, the concentration of Ti was analyzed by inductively coupled plasma (ICP) emission spectrometry and was compared with the above concentration of the Ti powder. The calculation result of the concentration during the mixing and the analysis result of the concentration of Ti after the sintering are shown in Table 3 below.

TABLE 3

| | | Concentration (analytical |
|---|---|---|
| | Concentration (atomic %) | value) (atomic %) of Ti |
| Test piece No. | of Ti powder during mixing | after sintering |
| T1 | 10.0 | 9.9 |
| T2 | 20.0 | 20.1 |
| T3 | 5.0 | 5.0 |
| T4 | 32.5 | 32.7 |

As shown in Table 3, as a result of comparison between the concentration of the Ti powder during the mixing of the Mo powder and the Ti powder and the analysis value of the concentration of Ti in the heat dissipation material after the sintering, only a slight difference within a degree of error is observed. Therefore, in this example, the concentration of the Ti powder and the concentration of the Mo powder during the mixing were regarded as the concentration of Ti and the concentration of Mo in the heat dissipation material after the sintering.

### (Calculation of Relative Density D and Alloying Ratio A)

The relative density D and the alloying ratio A of the obtained Mo—Ti sintered body (heat dissipation material) were calculated. The relative density D can be calculated according to the following equation (3).

$$D = ( {d}_{m} / {d}_{t} ) \times 100 \qquad Equation ( 3 )$$

dₘ is a density of the sintered body measured by using an underwater substitution method, and dₜ is a theoretical density dₜ calculated according to the following equation (4).

dₜ=100/([content of Ti]/[specific gravity of Ti]+[content of Mo]/[specific gravity of Mo]) Equation (4):

In the above equation (4), the [content of Ti] is the content of Ti contained in the heat dissipation material, and here, a value representing the content of the Ti powder in the raw material powder in mass % was used. The [specific gravity of Ti] is a value representing the specific gravity of pure Ti. In addition, the [content of Mo] is the content of Mo contained in the heat dissipation material, and here, a value representing the content of the Mo powder in the raw material powder in mass % was used. The [specific gravity of Mo] is a value representing the specific gravity of pure Mo. Note that, the specific gravity of pure Ti is 4.508, and the specific gravity of pure Mo is 10.222.

In addition, in order to calculate the alloying ratio A, the sintered body was subjected to measurement by using an X-ray diffraction method (XRD), and the concentrations of the Mo phase, the MoₓTi_{y} phase, and the Ti phase were measured by performing analysis by using a WPPF method using a spectrum having a 2θ angle of up to 20° to 140°. Conditions such as a program used for the analysis in the WPPF method and measurement conditions in the XRD are shown below.

### Analysis Conditions in WPPF Method

Analysis program: JADE manufactured by Materials Data Inc. (MDI)
PRO (version 8)
Database: ICDD PDF-4+

### Measurement Conditions in XRD

Micro X-ray diffractometer: RINT-RAPIDII manufactured by Rigaku Corporation
Collimator diameter: 300 μm
ω angle: 20° to 25° (2°/sec)
φ angle: rotation (1°/sec)

The alloying ratio A was calculated based on the content of the Mo phase in the sintered body and the concentration ([total Mo] (atomic %)) of all Mo contained in the sintered body, which were obtained by the XRD analysis, using the following equation (1). Note that, in the following equation (1) and equation (2), the [Mo phase] is a value representing the ratio of the Mo atoms constituting the Mo phase in the sintered body in atomic %, and the [total Mo] is a value representing the concentration of all Mo contained in the sintered body in atomic %, as determined by using the X-ray diffraction method. In addition, the {Mo phase} is the mass fraction of the Mo phase determined by using the XRD, and is a value representing the ratio of the Mo phase in mass % in the case where the total of the Mo phase, the MoₓTi_{y} phase, and the Ti phase is 100 mass %. The [content of Mo] is a value representing the content of all Mo contained in the sintered body in mass %. The [content of Ti] is a value representing the content of all Ti contained in the sintered body in mass %. As described above, as the concentration of Mo in the sintered body, the concentration of the Mo powder in the raw material powder can be used.

$$A = ( 1 - [ Mo phase ] / [ total Mo ] ) \times 100 \qquad Equation ( 2 )$$

$$[ Mo phase ] = ( \{ Mo phase \} / atomic weight of Mo ) / ( [ content of Mo ] / atomic weight of Mo + [ content of Ti ] / atomic weight of Ti )$$

### (Measurement of Thermal Conductivity and Linear Expansion Coefficient)

The thermal conductivity and the linear expansion coefficient were measured in the same manner as in the above Example 1. Various measurement results and calculation results for Inventive Example Nos. 21 to 29 are shown in Table 4 below. Note that, in Table 4 below, Inventive Example No. 21 is Inventive Example No. 4 in the above Example 1, and Inventive Example No. 29 is Inventive Example No. 3 in the above Example 1.

TABLE 4

| | | | | | Property evaluation | |
|---|---|---|---|---|---|---|
| | | | | Relative | Thermal | Linear expansion |
| | | Concentration | Alloying | density D | conductivity | coefficient |
| No. | | of Ti (atomic %) | ratio A (%) | (%) | (W/m · K) | (ppm/° C.) |
| Inventive | 21 | 32.5 | 51.3 | 100.0 | 33.5 | 6.76 |
| Example | 22 | 32.5 | 43.9 | 101.6 | 34.1 | 6.94 |
| | 23 | 32.5 | 41.8 | 100.0 | 34.7 | 6.72 |
| | 24 | 32.5 | 43.1 | 100.8 | 32.4 | 6.74 |
| | 25 | 32.5 | 48.2 | 101.1 | 31.7 | 6.78 |
| | 26 | 32.5 | 57.3 | 101.4 | 30.1 | 6.79 |
| | 27 | 32.5 | 57.6 | 101.1 | 30.1 | 6.76 |
| | 28 | 32.5 | 21.9 | 98.7 | 40.1 | 6.59 |
| | 29 | 5 | 0.4 | 96.4 | 87.7 | 5.68 |

### (Evaluation of Inventive Examples)

FIG. 4 is a graph showing a relationship between the relative density and the alloying ratio in the case where the vertical axis represents the relative density and the horizontal axis represents the alloying ratio. As shown in FIG. 4, it is found that, as the alloying ratio increases, the value of the relative density also increases and approaches 100%. In addition, in Inventive Examples in which the alloying ratio is 15% to 80% as indicated by a range of an arrow in FIG. 4, a particularly good relative density is exhibited. Further, when the alloying ratio is in the range of 30% or more, the relative density is further increased, and a value close to or more than 100% can be obtained.

As shown in the above Example 1 and Example 2, in the heat dissipation material in which the Mo phase and the Ti phase coexist, by controlling the content of Ti within a predetermined range and further controlling the alloying ratio within an appropriate range, it is possible to obtain a sound heat dissipation material having not only an excellent thermal conductivity and linear expansion coefficient but also a high relative density. In the base plate using the heat dissipation material obtained in this manner, there is no concern that the refrigerant leaks, and it is possible to prevent the occurrence of cracking or breakage that occurs in the case where a thermal or mechanical stress is applied, and it is possible to increase the lifetime of the base plate and to improve the reliability.

Although various embodiments have been described above with reference to the drawings, it is needless to say that the present invention is not limited to such examples. It is apparent that those skilled in the art can conceive of various modifications and alterations within the scope described in the claims, and it is understood that such modifications and alterations naturally fall within the technical scope of the present invention. In addition, the respective constituent elements in the above embodiments may be freely combined without departing from the gist of the invention.

Note that, the present application is based on a Japan patent application (No. 2023-092511) filed on Jun. 5, 2023 and a Japanese patent application (No. 2024-059528) filed on Apr. 2, 2024, contents of which are incorporated herein by reference.

### REFERENCE SIGNS LIST

1 Mo phase
2 Ti phase
10 electrostatic chuck
11 base plate
13 refrigerant flow path
12 ceramic layer
14 electrode

1. A heat dissipation component or a part thereof,
comprising a heat dissipation material, comprising:
a Mo phase; and
a Ti phase coexistent with the Mo phase,
wherein the heat dissipation material comprises Ti in a range of from 3 to 50 atomic % and Mo and unavoidable impurities as a remainder.

2. The component or part of claim 1, wherein the heat dissipation material consists of:
Ti: 3 atomic % or more and 50 atomic % or less in a case where a total of a content of Ti and a content of Mo is 100 atomic %,
O: 0 atomic % or more and 3 atomic % or less in the case where the total of the content of Mo and the content of Ti is 100 atomic %,
N, C, Fe, Si, Mn, Mg, CI, Al, V, Ni, and Nb: each 0 atomic % or more and 1 atomic % or less in the case where the total of the content of Mo and the content of Ti is 100 atomic %, and
the remainder being Mo and unavoidable impurities.

3. A heat dissipation component or a part thereof, comprising a heat dissipation material, comprising:
a Mo phase; and
a Ti phase coexistent with the Mo phase,
wherein the heat dissipation material comprises Ti in a range of from 3 to 50 atomic %, a remainder being Mo.

4. The component or part of claim 1, wherein the heat dissipation material has an alloying ratio A according to equation (1) of 15% or more and 80% or less, as measured by X-ray diffraction:
$$A = ( 1 - [ Mo phase ] / [ total Mo ] ) \times 100 , \qquad ( 1 )$$
wherein
[Mo phase] is a concentration of the Mo in the Mo phase of the heat dissipation material in atomic %,
[total Mo] a concentration of all the Mo in the heat dissipation material in atomic %, and
A is the alloying ratio.

5-7. (canceled)

8. A method for producing the heat dissipation component or part of claim 1, the method comprising:
mixing a powder comprising Mo and a powder comprising Ti, to obtain a mixture; and
sintering the mixture.

9. The component or part of claim 2, wherein the heat dissipation material has an alloying ratio A according to equation (1) of 15% or more and 80% or less, as measured by X-ray diffraction:
$$A = ( 1 - [ Mo phase ] / [ total Mo ] ) \times 100 , \qquad ( 1 )$$
wherein
[Mo phase] is a concentration of the Mo in the Mo phase of the heat dissipation material in atomic %,
[total Mo] a concentration of all the Mo in the heat dissipation material in atomic %, and
A is the alloying ratio.

10. The component or part of claim 3, wherein the heat dissipation material has an alloying ratio A according to equation (1) of 15% or more and 80% or less, as measured by X-ray diffraction:
$$A = ( 1 - [ Mo phase ] / [ total Mo ] ) \times 100 , . \qquad ( 1 )$$
wherein
[Mo phase] is a concentration of the Mo in the Mo phase of the heat dissipation material in atomic %,
[total Mo] a concentration of all the Mo in the heat dissipation material in atomic %, and
A is the alloying ratio.

11. A method for producing the component or part of claim 2, the method comprising:
mixing a powder comprising Mo and a powder comprising Ti, to obtain a mixture; and
sintering the mixture.

12. A method for producing the component or part of claim 3, the method comprising:
mixing a powder comprising Mo and a powder comprising Ti, to obtain a mixture; and
sintering the mixture.
